(19) United States
(12) Patent Application Publication
(10) Pub. No.: US 2012/0121807 A1
(43) Pub. Date: May 17, 2012

(54) FILM DEPOSITION SYSTEM AND METHOD AND GAS SUPPLYING APPARATUS BEING USED THEREIN

(75) Inventors: Ming-Tung Chiang, Hsinchu City (TW); Shih-Chin Lin, Taipei City (TW)

(73) Assignee: INDUSTRIAL TECHNOLOGY RESEARCH INSTITUTE, Hsinchu (TW)

(21) Appl. No.: 13/011,368

(22) Filed: Jan. 21, 2011

(30) Foreign Application Priority Data
Nov. 16, 2010 (TW) 099139329

(51) Int. Cl. C23C 16/455; F15D 1/00; C23C 16/18; C23C 16/448; C23C 16/46

(52) U.S. Cl. 427/255.23; 118/724; 137/334

(57) ABSTRACT

The present invention provides a film deposition system and method by combining a plurality of gas supplying apparatuses and a deposition apparatus being in communication with the plurality of gas supplying apparatuses. By means of respectively providing different types of vapor precursors with high concentration and high capacity into a process chamber of the deposition apparatus through the plurality of gas supplying apparatus, the deposition reaction is accelerated so as to improve the efficiency of film deposition. In an embodiment of the gas supplying apparatus, it utilizes a first gas for providing high pressure toward on a liquid surface of the precursor, thereby transporting the precursor into an atomizing and heating unit whereby the precursor is atomized and then is heated so as to form a high-concentration and high capacity vapor precursor transported by another carrier gas.

### CROSS-REFERENCE TO RELATED APPLICATIONS

This non-provisional application claims priority under 35 U.S.C. §119(a) on Patent Application No(s). 099139329 filed in Taiwan, R.O.C. on Nov. 16, 2010, the entire contents of which are hereby incorporated by reference.

### TECHNICAL FIELD

The present disclosure relates to a film depositing technique, and more particularly, to a film deposition system and method and gas supplying apparatus being used therein.

### TECHNICAL BACKGROUND

Generally, the deposition of transparent conductive film in solar cell production is performed either by means of physical vapor deposition (PVD) or by means of chemical vapor deposition (CVD). Nevertheless, for the PVD film deposition, since the texturing of the resulting films is usually performed by means of etching, it is disadvantageous not only in terms of increasing process complexity, but also in terms of lower deposition ratio due to the use of the PVD process. On the other hand, for the CVD film deposition, since it is required to enable the precursors to be fed into the showerhead module inside the reaction chamber with the flowing of carrier gases, it is disadvantageous not only in terms of low concentration of precursors in carrier gases, but also in terms of decreasing deposition speed due to the low concentration.

Please refer to FIG. 1, which is a schematic diagram showing a conventional film deposition system. In FIG. 1, the film deposition system includes a film deposition apparatus 10 and two gas supplying apparatuses 11 and 12. Operationally, the precursors 110 and 120, that are stored inside two containers of the two gas supplying apparatuses 11, 12 in respective, are first being atomized into vapor precursors by feeding an inert gas 90, such as Argon (Ar), respectively into the two containers, and then the vapor precursors vapors are fed into the showerhead module 100 inside the film deposition apparatus 10 so as to be discharged and distributed into the reaction chamber for depositing a film on the substrate 101. However, since the vapor precursors being fed into the reaction chamber using the aforesaid gas supplying apparatuses are low in concentration and also low in capacity, causing low deposition efficiency and low film growth rate as the consequence, the manufacturing cost of the aforesaid film deposition system can be comparatively higher. Moreover, in another film deposition system disclosed in U.S. Pat. No. 5,002,796, similarly, a carrier gas being fed into containers containing liquid-state precursors will bring the precursors to flow out of the container with the flowing of the same and then into a tubing system where the precursors will be energized by a microwave projection before being introduced into the film deposition apparatus. However, although the chemical reactions for film deposition are enhanced by the energized precursors, the capacity of the precursor being transported is still not improved and thus the film deposition efficiency is still unsatisfactory.

### TECHNICAL SUMMARY

The present disclosure related to a film deposition system and method, in that gas supplying apparatuses will first enable their corresponding precursors to be atomized and then enable the atomized precursors to be vaporized into high-concentration and high-capacity vapor precursors so as to be fed into a process chamber in respective, and thereafter, inside the process chamber, the high-concentration and high-capacity vapor precursors are premixed using a showerhead module before being uniformly distributed onto a surface of a substrate for achieving not only the increasing in film deposition rate while simultaneously enhancing the uniformity of the film being deposited on a large-area substrate by the use of the showerhead module. Thereby, the characteristic of transparent conductive film being deposited thereby can be ensured for the transparency thereof is improved and the sheet resistance thereof can be reduced while the uniform of the thickness are enhanced effectively.

The present disclosure also relates to a gas supplying apparatus, capable of first atomizing a precursor and then enabling the atomized precursor to be heated and thus vaporized into a vapor precursor so as to be transported using a flow of a specific amount of a carrier gas for outputting the vapor precursor with high concentration and high capacity.

In an exemplary embodiment, the present disclosure provides a film deposition system, comprising: a film deposition apparatus; and a plurality of gas supplying apparatuses, coupled respectively to the film deposition apparatus, each further comprising: a heating unit; a container having a precursor stored therein in its liquid state; a first tubing system, for guiding a first gas to flow therein, the first tubing system having a tube-opening arranged inside the container at a position spaced from the liquid surface of the precursor by a specific distance; a second tubing system being configured with a first opening and a second opening in a manner that the first opening is arranged inside the container at a position below the liquid surface of the precursor and the second opening is connected to the heating unit; and a third tubing system, for guiding a second gas to flow into the heating unit; wherein, in each gas supplying apparatus, the first gas is guided to be discharged out of the tube-opening for exerting a pressure upon the liquid surface of the corresponding liquid precursor, and thus pressurizing the liquid precursor to flow into the second tubing system through the first opening where it is further being guided to flow into the heating unit, and simultaneously, the second gas, being guided by the third tubing system, is enabling to flow at high speed and rushing into the heating unit for atomizing the liquid precursor into an atomized precursor while enabling the atomized precursor to mix with the second gas so as to formed a mixture of the gaseous second gas and the atomized precursor, and then the mixture is heated by the heating unit for transforming the atomized precursor into a vapor precursor that is to be transported by the flowing of the second gas to the film deposition apparatus.

In another exemplary embodiment, the present disclosure provides a film deposition method, comprising the steps of: providing a plurality of containers to be used for storing a plurality of precursors in their liquid states, while enabling each container to be connected to a first tubing system and a second tubing system in a manner that the first tubing system is arranged for enabling a tube-opening thereof to be disposed inside the corresponding container at a position spaced from the liquid surface of the corresponding precursor by a specific distance, and the second tubing system is arranged for enabling a first opening thereof to be disposed inside the corresponding container at a position below the liquid surface of the corresponding precursor while enabling a second opening thereof to connect to a heating unit whereas the heating unit is provided for receiving a second gas to flow therein; respectively feeding a first gas to each first tubing system for allowing the same to be discharged out of the corresponding tube opening and thus exerting a pressure upon the liquid surface of the corresponding liquid precursor so as to pressurize the liquid precursor to flow into the corresponding second tubing system where it is further being guided to flow into the corresponding heating unit; enabling the heating unit to atomize the liquid precursor into an atomized precursor while enabling the atomized precursor to mix with the second gas so as to formed a mixture of the gaseous second gas and the atomized precursor, that is to be heated by the heating unit and thus vaporized into a vapor precursor so as to be mixed with the second gas and thus forming a third gas; transporting the third gas from each heating unit to a showerhead module arranged inside a film deposition apparatus; and enabling the showerhead module to distribute the plural third gases received from different heating units on a substrate inside the film deposition apparatus for activating a chemical reaction on the surface of the substrate so as to form a film.

In further another exemplary embodiment, the present disclosure provides a gas supplying apparatus, comprising: a heating unit; a container, for storing a precursor in its liquid state; a first tubing system, for guiding a first gas to flow therein, having a tube opening arranged inside the container at a position spaced from the liquid surface of the precursor by a specific distance; a second tubing system, configured with a first opening and a second opening in a manner that the first opening is arranged inside the container at a position below the liquid surface of the precursor and the second opening is connected to the heating unit; and a third tubing system, for guiding a second gas to flow into the heating unit; wherein, the first gas is guided to be discharged out of the tube opening for exerting a pressure upon the liquid surface of the corresponding liquid precursor, and thus pressurizing the liquid precursor to flow into the second tubing system through the first opening where it is further being guided to flow into the heating unit, and simultaneously, the second gas, being guided by the third tubing system, is enabling to flow at high speed and rushing into the heating unit for atomizing the liquid precursor into an atomized precursor while enabling the atomized precursor to mix with the second gas so as to formed a mixture of the gaseous second gas and the atomized precursor, and then the mixture is heated by the heating unit for transforming the atomized precursor into a vapor precursor that is to be transported out of the heating unit by the flowing of the second gas.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a schematic diagram showing a conventional film deposition system.

FIG. 2 is a schematic diagram showing a film deposition system according to the present disclosure.

FIG. 3 is a schematic diagram showing a gas supplying apparatus used in the present disclosure.

FIG. 4 is a schematic diagram showing a heating unit used in the present disclosure.

FIG. 5 is a flow chart depicting the steps performed in a film deposition method of the present disclosure.

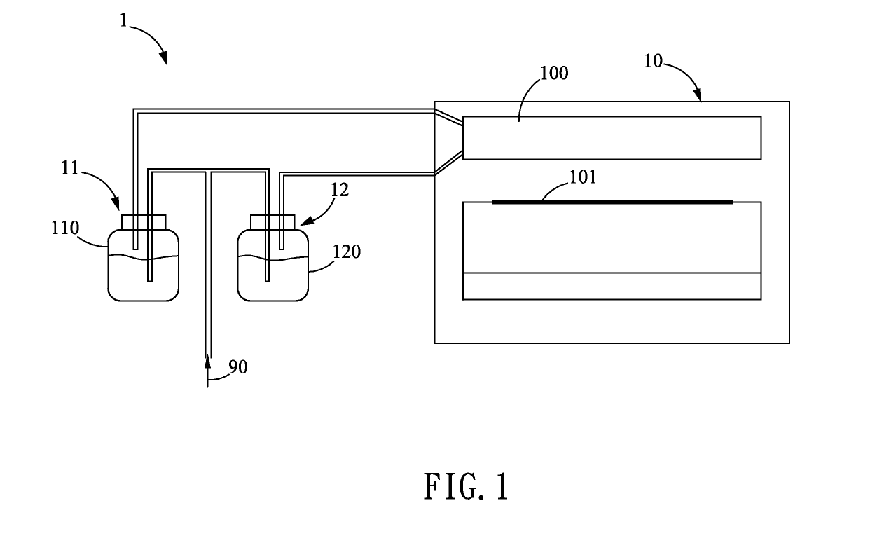

### DESCRIPTION OF THE EXEMPLARY EMBODIMENTS

For your esteemed members of reviewing committee to further understand and recognize the fulfilled functions and structural characteristics of the disclosure, several exemplary embodiments cooperating with detailed description are presented as the follows.

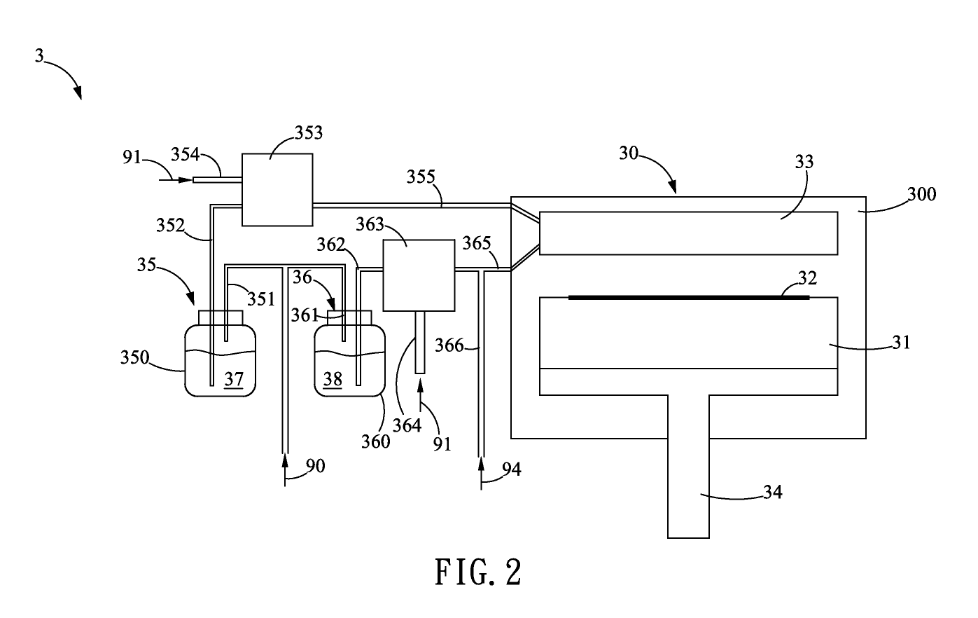

Please refer to FIG. 2, which is a schematic diagram showing a film deposition system according to the present disclosure. In FIG. 2, the film deposition system 3 comprises a film deposition apparatus 30 and a plurality of gas supplying apparatuses, in which the film deposition apparatus 30 is formed with a process chamber 300, whereas the process chamber 300 has a heater 31 disposed therein, that is provided for a substrate 32 to be disposed thereon. It is noted that the substrate 32 can be a silicon substrate or a glass substrate, but is not limited thereby. Moreover, inside the process chamber 300, there is a showerhead module 33 being disposed at a position above the heater 31 while being connected to the plural gas supplying apparatuses, so that the showerhead module 33 inside the process chamber 300 is used for pre-mixing the precursors from the plural gas supplying apparatuses and then enabling the mixture of those precursors to be distributed uniformly onto the substrate 32. In this embodiment, the film deposition apparatus can substantially be a vacuum film deposition apparatus or an atmospheric-pressure film deposition apparatus, and accordingly, the showerhead module 33 can be structured as the showerhead module disclosed in TW Pat. Pub. No. 201021095, which is a prior art and thus is not described further herein. In addition, the heater 31 is further connected to a lift mechanism 34 that is disposed under the heater 31 to be used for driving the heater 31 to move upward or downward, and consequently, enabling the distance between the substrate and the showerhead module 33 to be changed accordingly, by that an optimal film deposition position can be obtained. By arranging the heater 31 to be positioned at the optimal film deposition position, not only the uniformity of the precursors that are to be distributed by the showerhead module 33 onto the substrate can be improved, but also the waste of the precursors in a film deposition process can be minimized. In this embodiment, the lift mechanism 34 can be constructed as a ball screw being driven by a motor, but it is not limited thereby and can be constructed as pneumatic driving mechanism or a cam driving mechanism, etc.

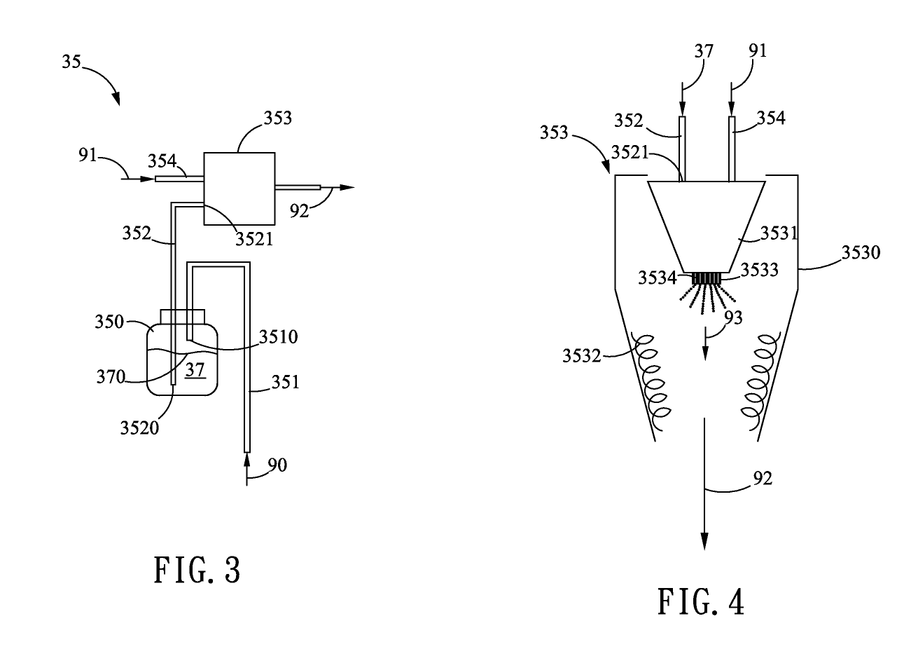

In the embodiment shown in FIG. 2, there are two gas supplying apparatuses 35 and 36, each composed of a container, a first tubing system, a second tubing system, a heating unit, a third tubing system and an output tubing system. That is, the container 350, the first tubing system 351, the second tubing system 352, the heating unit 353, the third tubing system 354 and the output tubing system 355 for the gas supplying apparatus 35; and the container 360, the first tubing system 361, the second tubing system 362, the heating unit 363, the third tubing system 364 and the output tubing system 365 for another gas supplying apparatus 36. Since the two gas supplying apparatuses 35 and 36 are constructed exactly the same, the gas supplying apparatus 35 is selected for illustration, as shown in FIG. 3. In FIG. 3, the container 350 is provided for storing a precursor 37 in its liquid state, which can be an oxygen-bearing functional group precursor, such as H₂O, but is not limited thereby, or can be an organo-metallic compounds precursor, such as diethylzinc (DEZn), but also is not limited thereby. Moreover, the first tubing system 351, being provided for guiding a first gas 90, has a tube-opening 3510 arranged inside the container 350 at a position spaced from the liquid surface of the precursor 37 by a specific distance, whereas the first gas 90 is used to compressing precursors out, and can be an inert gas or nitrogen, but is not limited thereby. In this embodiment, the first gas 90 is selected to be Argon (Ar).

In addition, the second tubing system 352, being arranged inside the container 350, is configured with a first opening 3520 and a second opening 3521 in a manner that the first opening 3520 is arranged inside the container 350 at a position below the liquid surface 370 of the precursor 37 while enabling the second opening to be connected to the heating unit 353. The third tubing system 354 is provided for guiding a second gas 91 to flow into the heating unit 353, as the second gas 91 is provided to act as a carrier gas for transporting the precursor 37. Similarly, the second gas 91 can be an inert gas or nitrogen, but is not limited thereby. In this embodiment, the second gas 91 is selected to be Argon (Ar). It is noted that the first gas 90 and the second gas 91 can be the same inert gas or different inert gases.

As shown in FIG. 3, in the gas supplying apparatus 35, the first gas 90 is guided to be discharged out of the tube-opening 3510 of the first tubing system 351 for exerting a pressure upon the liquid surface 370 of the liquid precursor 37, and thus pressurizing the liquid precursor 37 to flow into the second tubing system 352 through the first opening 3520 where it is further being guided to flow into the heating unit 353, and simultaneously, the second gas 91, being guided by the third tubing system 354, is enabling to flow at high speed and rushing into the heating unit 353 for atomizing the liquid precursor 37 into an atomized precursor while enabling the atomized precursor to mix with the second gas 91 so as to formed a mixture of the gaseous(?) second gas and the atomized precursor, and then the mixture is heated by the heating unit 353 for transforming the atomized precursor into a vapor precursor, that is mixed with the second gas 91 into a third gas 92 so as to be transported by the flowing of the second gas 91 out of the heating unit 353. Thereby, by the operation inside the heating unit 353, the precursor being transported with the flow of the second gas 91 is a vapor precursor with high concentration and high capacity.

Please refer to FIG. 4, which is a schematic diagram showing a heating unit used in the present disclosure. In FIG. 4, the heating unit 353 is composed of a chamber 3530, an atomizer 3531 and a heating component 3532. Wherein, the atomizer 3531, disposed inside the chamber 3530 while connecting to the second opening 3521 and the third tubing system 354 through a side thereof, has a nozzle 3533, that is formed with a plurality of via holes 3534, to be arranged on a surface thereof; and the heating component 3532 is disposed inside the chamber 3530 at a position proximate to a side of the nozzle 3533. In this embodiment, the heating component 3532 is a ring-like electric heating filament that is attached to the inner wall of the chamber 3530, but it is not limited thereby. Operationally, when the precursor 37 is fed to the atomizer 3531 through the second tubing system 352, the second gas 91 is also being fed into the atomizer 3531 at high speed through the third tubing system 354 and collides with the liquid precursor 37 for atomizing the same.

Thereafter, the flow of the second gas 91 will blow through the nozzle 3533 along with the atomized precursor which will further disperse the atomized precursor into even smaller droplets so as to be mixed again with the second gas 91, forming a mixture 93 of the second gas 91 and the atomized precursor. Then, the mixture 93 that is discharged out of the atomizer 3531 will be heated by the heating component 3532 for transforming the atomized precursor of the mixture 93 into a vapor precursor. It is noted that the atomizer 3531 is not limited by the aforesaid embodiment. For instance, the atomizer 3531 can be configured with a high-frequency oscillator, such as an ultrasonic oscillator, which is used for enabling a micro-nozzle plate to vibrate stably at a high frequency and thus atomizing a liquid by the high-frequency vibration. It is noted that the technique relating to the high-frequency oscillator is known to those skilled in the art, and thus is not described further herein.

Back to the embodiment shown in FIG. 2, the oxygen-bearing functional group precursor stored inside the container 350 of the gas supplying apparatus 35 is water (H₂O), for example, and the organo-metallic compounds precursor stored inside the container 360 of the gas supplying apparatus 36 is DEZn; whereas the two output tubing systems 355 and 365 of the two heating units 353 and 363 are all connected to the showerhead module 33, whereas each of the two heating units 353 and 363 is constructed the same as the one shown in FIG. 4 so as to atomize and then heat the precursor being fed into the same for transforming the liquid precursor into vapor precursor. In addition, the output tubing system 365 of the gas supplying apparatus 36 for providing the organo-metallic compounds vapor precursor is further connected with a tubing system 366 provided for transporting a doping material 94 to be mixed with the gas of the output tubing system 365. In this embodiment, the doping material 94 can be a mixture of H₂B₆ and H₂, but is not limited thereby.

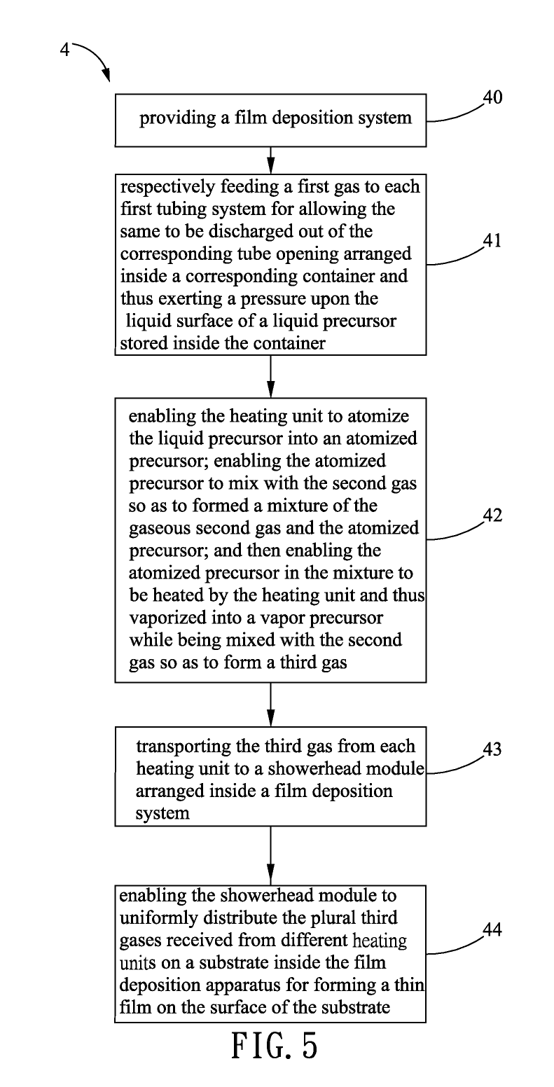

Please refer to FIG. 5, which is a flow chart depicting the steps performed in a film deposition method of the present disclosure. It is noted that the film deposition method of FIG. 5 can be performed using the film deposition system of FIG. 2. The film deposition method starts from step 40. At step 40, a film deposition system 3 as the one shown in FIG. 2 is provided; and then the flow proceeds to step 41. Similarly, in this embodiment, the precursor 37 stored inside the container 350 is an oxygen-bearing functional group precursor, such as water; and the precursor 38 stored in the container 360 is an organo-metallic compounds precursor, such as DEZn. At step 41, a first gas 90 is fed to flow into the first tubing systems 351, 361 that are connected respectively to the two containers 35 and 36, while allowing the same to be discharged out of the tube-openings arranged inside their corresponding containers 35, 36 and thus exerting a pressure upon the liquid surface of the corresponding liquid precursors 37 and 38 for pressurizing the same to flow into their corresponding second tubing systems 352, 362 through their tube-openings arranged below the liquid surfaces and thus enter the corresponding heating units 353, 363; and then the flow proceeds to step 42. It is noted that the first gas 90 can be an inert gas or nitrogen, but is not limited thereby. In this embodiment, the first gas 90 is selected to be Argon (Ar).

At step 42, the two heating units 353, 363 are enabled to atomize the corresponding liquid precursors 37, 38 into an atomized precursor while enabling the atomized precursor to mix with the second gas 91 flowing therein through the corresponding third tubing systems 354, 364 for forming mixtures of the gaseous second gas 91 and the atomized precursors, and then the atomized precursors are provided to be heated respectively by their corresponding heating units 353, 363 and thus vaporized into vapor precursors so as to be mixed with the second gas, forming various third gases; and then the flow proceeds to step 43. As the second gas 91 is provided to act as a carrier gas for transporting the vapor precursors, the second gas 91 can be an inert gas or nitrogen, but is not limited thereby. In this embodiment, the second gas 91 is selected to be Argon (Ar). It is noted that the first gas 90 and the second gas 91 can be the same inert gas or different inert gases.

At step 43, each of the third gases from their corresponding heating units 353, 363 to the showerhead module 33, i.e. the showerhead module 33 in this embodiment will receive steam transported by the second gas 91 flowing from the gas supplying apparatus 35 and the DEZn organo-metallic compounds vapor transported by the second gas 91 flowing from the gas supplying apparatus 36; and then the flow proceeds to step 44. At step 44, the showerhead module 33 is enabled to uniformly distribute the plural third gases received from different heating units 353, 363 on a substrate 32 inside the film deposition apparatus 30 for forming a film on the surface of the substrate 32. It is noted that although the different third gases will be premixed inside the showerhead module 33 before being distributed onto the substrate 32 in this embodiment, there can be a showerhead module working in conjunction with the corresponding gas supplying apparatuses without having the third gases to be premixed before being distributed.

In one embodiment, after the precursors entering the showerhead module, they are enabled to diffuse serially in a X-axis direction and a Y-axis direction for eventually achieving a planar uniform distribution before being distributed toward the surface of a substrate, and consequently, a film with uniform thickness can be achieved.

With respect to the above description then, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A film deposition system, comprising:
a film deposition apparatus; and
a plurality of gas supplying apparatuses, coupled respectively to the film deposition apparatus, each further comprising:
a heating unit;
a container, having a precursor stored therein in its liquid state;
a first tubing system, for guiding a first gas to flow therein, having a tube-opening arranged inside the container at a position spaced from the liquid surface of the precursor by a specific distance;
a second tubing system, configured with a first opening and a second opening in a manner that the first opening is arranged inside the container at a position below the liquid surface of the precursor and the second opening is connected to the heating unit; and
a third tubing system, for guiding a second gas to flow into the heating unit;
wherein, in each gas supplying apparatus, the first gas is guided to be discharged out of the tube-opening for exerting a pressure upon the liquid surface of the corresponding liquid precursor, and thus pressurizing the liquid precursor to flow into the second tubing system through the first opening where it is further being guided to flow into the heating unit, and simultaneously, the second gas, being guided by the third tubing system, is enabling to flow at high speed and rushing into the heating unit for atomizing the liquid precursor into an atomized precursor while enabling the atomized precursor to mix with the second gas so as to formed a mixture of the gaseous second gas and the atomized precursor, and then the mixture is heated by the heating unit for transforming the atomized precursor into a vapor precursor that is to be transported by the flowing of the second gas to the film deposition apparatus through an output tubing system.

2. The film deposition system of claim 1, wherein each of the first gas and the second gas is a gas selected from the group consisting of: an inert gas and nitrogen.

3. The film deposition system of claim 1, wherein the heating unit further comprises:
a chamber;
an atomizer, disposed inside the chamber while connecting to the second opening and the third tubing system through a side thereof, having a nozzle with a plurality of via holes to be arranged on a surface thereof, provided for atomizing the liquid precursor into the atomized precursor as it is being brought along to flow through the nozzle by the rapidly flowing second gas, and thus to be mixed with the second gas and formed the mixture of the gaseous(?) second gas and the atomized precursor; and
a heating component, disposed inside the chamber for heating the atomized precursor and thus transforming the same into the vapor precursor.

4. The film deposition system of claim 1, wherein the plural gas supplying apparatuses includes at least one gas supplying apparatus for providing steam or an oxygen-bearing functional group gas, and at least one gas supplying apparatus for providing an organo-metallic compounds vapor.

5. The film deposition system of claim 4, wherein the output tubing system of any gas supplying apparatus for providing the organo-metallic compounds vapor is further connected with a tubing system provided for transporting a doping material.

6. The film deposition system of claim 1, wherein the film deposition apparatus is an apparatus selected from the group consisting of: a vacuum film deposition apparatus and an atmospheric-pressure film deposition apparatus.

7. A film deposition method, comprising the steps of:
providing a plurality of containers to be used for storing a plurality of precursors in their liquid states, while enabling each container to be connected to a first tubing system and a second tubing system in a manner that the first tubing system is arranged for enabling a tube-opening thereof to be disposed inside the corresponding container at a position spaced from the liquid surface of the corresponding precursor by a specific distance, and the second tubing system is arranged for enabling a first opening thereof to be disposed inside the corresponding container at a position below the liquid surface of the corresponding precursor while enabling a second opening thereof to connect to a heating unit whereas the heating unit is provided for receiving a second gas to flow therein;
respectively feeding a first gas to each first tubing system for allowing the same to be discharged out of the corresponding tube-opening and thus exerting a pressure upon the liquid surface of the corresponding liquid precursor so as to pressurize the liquid precursor to flow into the corresponding second tubing system where it is further being guided to flow into the corresponding heating unit;
enabling the heating unit to atomize the liquid precursor into an atomized precursor while enabling the atomized precursor to mix with the second gas so as to formed a mixture of the gaseous second gas and the atomized precursor, that is to be heated by the heating unit and thus vaporized into a vapor precursor so as to be mixed with the second gas and thus forming a third gas;
transporting the third gas from each heating unit to a showerhead module arranged inside a film deposition apparatus; and
enabling the showerhead module to distribute the plural third gases received from different heating units on a substrate inside the film deposition apparatus for forming a thin film on the surface of the substrate.

8. The film deposition method of claim 7, wherein each of the first gas and the second gas is a gas selected from the group consisting of: an inert gas and nitrogen.

9. The film deposition method of claim 7, wherein the heating unit further comprises:
a chamber;
an atomizer, disposed inside the chamber while connecting to the second opening and the third tubing system through a side thereof, having a nozzle with a plurality of via holes to be arranged on a surface thereof, provided for atomizing the liquid precursor into the atomized precursor as it is being brought along to flow through the nozzle by the rapidly flowing second gas, and thus to be mixed with the second gas and formed the mixture of the gaseous second gas and the atomized precursor; and
a heating component, disposed inside the chamber for heating the atomized precursor and thus transforming the same into the vapor precursor.

10. The film deposition method of claim 7, wherein one of the containers is provided for storing an oxygen-bearing functional group precursor, and another one of the containers is provided for storing an organo-metallic compounds precursor, and thereby, the vapor precursors entering the showerhead module contains the gaseous oxygen-bearing functional group precursor and the gaseous organo-metallic compounds precursor.

11. The film deposition method of claim 10, further comprising a step of:
mixing the gaseous organo-metallic compounds precursor with a doping material prior to the entering of the gaseous organo-metallic compounds precursor into the showerhead module.

12. The film deposition method of claim 7, wherein the film deposition apparatus is an apparatus selected from the group consisting of: a vacuum film deposition apparatus and an atmospheric-pressure film deposition apparatus.

13. The film deposition method of claim 7, further comprising one step selected from the group consisting of: enabling the plural third gases to be premixed inside the showerhead module before being distributed uniformly onto the substrate for forming the thin film on the surface of the substrate; and enabling the plural third gases to distributed uniformly onto the substrate for forming the thin film on the surface of the substrate without being premixed inside the shower head.

14. A gas supplying apparatus, comprising:
a heating unit;
a container, for storing a precursor in its liquid state;
a first tubing system, for guiding a first gas to flow therein, having a tube-opening arranged inside the container at a position spaced from the liquid surface of the precursor by a specific distance;
a second tubing system, configured with a first opening and a second opening in a manner that the first opening is arranged inside the container at a position below the liquid surface of the precursor and the second opening is connected to the heating unit; and
a third tubing system, for guiding a second gas to flow into the heating unit;
wherein, the first gas is guided to be discharged out of the tube-opening for exerting a pressure upon the liquid surface of the corresponding liquid precursor, and thus pressurizing the liquid precursor to flow into the second tubing system through the first opening where it is further being guided to flow into the heating unit, and simultaneously, the second gas, being guided by the third tubing system, is enabling to flow at high speed and rushing into the heating unit for atomizing the liquid precursor into an atomized precursor while enabling the atomized precursor to mix with the second gas so as to formed a mixture of the gaseous second gas and the atomized precursor, and then the mixture is heated by the heating unit for transforming the atomized precursor into a vapor precursor that is to be transported out of the heating unit by the flowing of the second gas.

15. The gas supplying apparatus of claim 14, wherein each of the first gas and the second gas is a gas selected from the group consisting of: an inert gas and nitrogen.

16. The gas supplying apparatus of claim 14, wherein the heating unit further comprises:
a chamber;
an atomizer, disposed inside the chamber while connecting to the second opening and the third tubing system through a side thereof, having a nozzle with a plurality of via holes to be arranged on a surface thereof, provided for atomizing the liquid precursor into the atomized precursor as it is being brought along to flow through the nozzle by the rapidly flowing second gas, and thus to be mixed with the second gas and formed the mixture of the gaseous second gas and the atomized precursor; and
a heating component, disposed inside the chamber for heating the atomized precursor and thus transforming the same into the vapor precursor.
